(19) United States
(12) Patent Application Publication
(10) Pub. No.: US 2023/0357919 A1
(43) Pub. Date: Nov. 9, 2023

(54) EVAPORATION SOURCE FOR USE IN VAPOR DEPOSITION APPARATUS

(71) Applicant: ULVAC, INC., Kanagawa (JP)

(72) Inventors: Masashi Umehara, Kanagawa (JP); Hironori Wakamatsu, Kanagawa (JP); Toshimitsu Nakamura, Kanagawa (JP); Fumitsugu Yanagihori, Kanagawa (JP)

(73) Assignee: ULVAC, INC., Kanagawa (JP)

(21) Appl. No.: 18/041,893

(22) PCT Filed: Dec. 21, 2021
(86) PCT No.: PCT/JP2021/047233

§ 371 Date: Feb. 16, 2023

(30) Foreign Application Priority Data
Feb. 24, 2021 (JP) 2021-027979

(51) Int. Cl. C23C 14/24

(52) U.S. Cl. CPC C23C 14/243

(57) ABSTRACT

There is provided an evaporation source adapted for use in a vapor deposition apparatus in which by heating, in an induction heating method, a crucible filled with a vapor deposition material, the entire crucible including a cap body attains a top-heat state. An evaporation source is provided with: a crucible filled with the vapor deposition material; a cap body to close an upper surface opening of the crucible; and an induction heating coil disposed around the crucible and the cap body. Further, the cap body is provided with a discharge part which allows the passage of the vapor deposition material evaporated or sublimated by heating. The cap body is provided on an external surface thereof with projections each having a corner part.

### TECHNICAL FIELD

The present invention relates to an evaporation source for use in a vapor deposition apparatus in which the evaporation source is disposed inside a vacuum chamber for depositing on an object to be deposited (hereinafter also called “to-be-deposited object”), and relates in particular to the evaporation source for heating a vapor deposition material inside a crucible in an induction heating method.

### BACKGROUND ART

This kind of evaporation source for use in a vapor deposition apparatus is known, e.g., in patent document 1. The evaporation source is provided with: a crucible filled with a vapor deposition material; a cap body having a discharge nozzle (discharge part) which closes an opening on an upper surface of the crucible and which also allows passage of the vapor deposition material that has been vaporized or sublimated; and an induction heating coil which is disposed around the crucible and the cap body. In this arrangement, when the induction heating coil is charged with an AC current inside the vacuum chamber in a vacuum atmosphere, the crucible and the cap body are heated by Joule heat generated by resistance loss that is caused when induction current (eddy current) flows through the crucible and the cap body. As a consequence, the vapor deposition material inside the crucible is heated by heat conduction from a wall part of the crucible and radiant heat from the cap body.

It is to be noted here that, when the vapor deposition material inside the crucible is heated, the vapor deposition material inside the crucible is not vaporized or sublimated except from an upper layer portion that faces the discharge nozzle. Therefore, at the time of heating the crucible inclusive of the cap body, it is desirable to maintain a temperature gradient with high temperature of the cap body and lower temperature gradient toward the lower end of the crucible (so-called top-heat state) by efficiently heating only the upper layer portion of the vapor deposition material so that the vapor deposition material present in the lower layer portion inside the crucible does not suffer from a heat deterioration (thermal decomposition, thermal denaturation, and the like in case of organic materials) as a result of addition of excessive thermal load to the vapor deposition material. In such a case, in a resistance heating system by utilizing a sheathed heater, and the like, it is easy to attain the top-heat state, but in an induction heating system, a resistance loss will occur depending on a counter area relative to the induction heating coil. Therefore, as a consequence of heating on a priority basis the crucible having a relatively large counter area, if the entire crucible is heated so that the vapor deposition material on the upper layer portion reaches an evaporation temperature or a sublimation temperature, there is a problem in that the lower part of the crucible will attain an excessive heat state (so-called bottom-heat state).

As compared with the resistance heating system, the induction heating system has an advantage in that the responsiveness in heating is better and that heat can be dissipated at a short time after having finished the deposition work. For this reason, development of the induction type of evaporation source that is capable of attaining the top-heat state of the crucible inclusive of the cap body is desired.

### PATENT DOCUMENTS

Patent Document 1: JP2004-134250A

### SUMMARY OF THE INVENTION

### Problems that the Invention is to Solve

In view of the above-mentioned points, this invention has a problem of providing an evaporation source for use in a vapor deposition apparatus in which, when a crucible filled with a vapor deposition material is heated in the induction heating system, the entire crucible including the cap body becomes a top-heat state.

### Means for Solving the Problems

In order to solve the above-mentioned problem, this invention is an evaporation source disposed inside a vacuum chamber, the evaporation source being adapted for use in a vapor deposition apparatus which performs vapor deposition on a to-be-deposited object. The evaporation source comprises: a crucible filled with a vapor deposition material; a cap body for closing an upper surface opening of the crucible; an induction heating coil disposed around the crucible and the cap body; and a discharge part disposed in the cap body in order to allow for passage therethrough of the vapor deposition material that has been evaporated or sublimated by heating, wherein the cap body is provided on an outside surface thereof with projections each having a corner part.

According to this invention, when an AC current is charged through the induction heating coil inside the vacuum chamber in a vacuum atmosphere, an induction current (eddy current) flows through the crucible and the cap body. At this time, since projections each having a corner part on an outside surface of the cap body are provided, resistance loss will be augmented at the corner parts (edge parts) of the projections. In other words, the calorific value improves when the magnetic flux density to work on the cap body and the quality of material of the cap body are supposed to be equal to a case, for comparison purpose, in which projections are not provided. As a result, it becomes possible to cause the cap body to generate heat on a priority basis so that the entire crucible inclusive of the cap body can be made into the top-heat state. By the way, in this invention, when the “corner parts” of the projections are referred to, it should be understood to include not only the case in which the projections have square profiles but also the case in which the projections are rounded to such a degree as to be able to increase the resistance losses (e.g., having a profile of ellipse).

In this invention, preferably the cap body comprises: a cover plate part provided with the discharge part; and a peripheral wall part vertically disposed from an outer edge of the cover plate part downward such that: a lower end of the peripheral wall part is detachably fitted onto an upper end of the crucible and that; an outside surface of the peripheral wall part is provided with a plurality of the above-mentioned projections in a manner to be vertically or circumferentially extended. According to this arrangement, the outside surface of the peripheral wall part has a shape of repeating projections so that the length for the eddy current to flow therethrough becomes longer, thereby still further augmenting the resistance loss. The calorific value of the cap body can further be augmented so that the entire crucible including the cap body can surely be made to be the top-heat state.

By the way, in order to attain the top-heat state of the crucible inclusive of the cap body in case the cap body is not provided with projections, it may be considered to set smaller the winding pitch of the induction heating coil that is positioned around the cap body than the winding pitch of the induction heating coil that is positioned around the crucible, thereby creating magnetic flux densities into coarse one and dense one. However, the counter area of the cap body that lies opposite to the induction heating coil is still smaller in this arrangement. It is therefore still far from attaining the top-heat state. On the other hand, according to this invention, the winding pitch of the induction heating coil that is positioned around the cap body is set smaller than the winding pitch of the induction heating coil that is positioned around the crucible. In this arrangement, the eddy current to flow through the crucible becomes smaller, and therefore the crucible is restrained from getting heated and, consequently, the entire crucible inclusive of the cap body can surely be made to the top-heat state.

### BRIEF DESCRIPTION OF THE DRAWINGS

FIG. 1 is a patial perspective view to explain an arrangement of a vapor deposition apparatus according to this embodiment.

FIG. 2 is an enlarged sectional view of an evaporation source according to a first embodiment of this invention.

FIG. 3 is a partially enlarged sectional view of a modified example according to the first embodiment of this invention.

FIG. 4 is an enlarged sectional view of an evaporation source according to the second embodiment of this invention.

### MODES FOR CARRYING OUT THE INVENTION

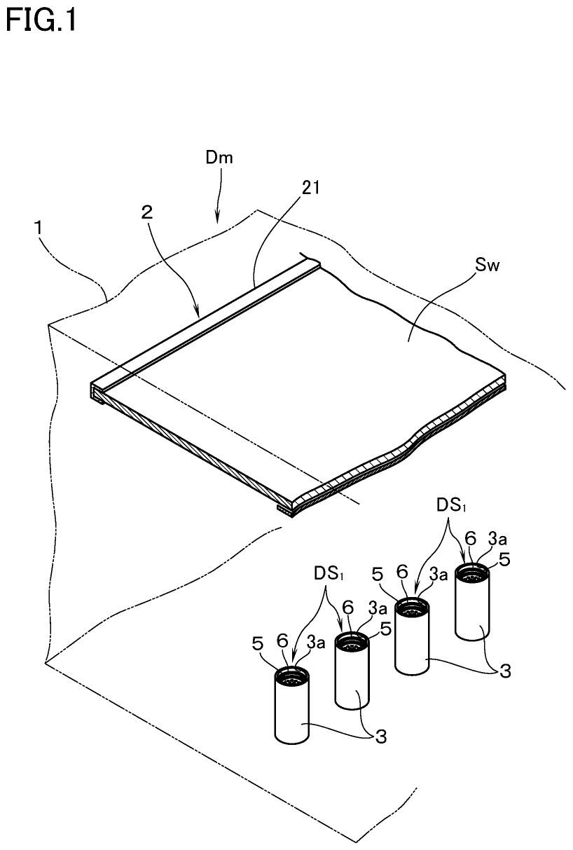

With reference to the drawings, a to-be-deposited object is defined as a glass substrate (hereinafter referred to as “substrate Sw”) of a predetermined thickness having a rectangular profile. A description will now be made of an evaporation source DS adapted for use in a vapor deposition apparatus with reference to an example in which a predetermined thin film is formed on one surface of the substrate Sw by vapor deposition. In the following descriptions, the terms showing the directions such as “upper”, “lower”, and the like are described on the basis of FIG. 1.

With reference to FIG. 1, reference character Dm is a vapor deposition apparatus provided with evaporation sources DS₁ according to a first embodiment of this invention. The vapor deposition apparatus Dm is provided with a vacuum chamber 1 to which, although not explained by particularly illustrating, is connected a vacuum pump through an exhaust pipe. It is thus so arranged that the vacuum chamber 1 can be maintained inside thereof at a predetermined pressure (vacuum degree). Further, at an upper part of the vacuum chamber 1 there is provided a substrate transfer apparatus 2. The substrate transfer apparatus 2 has a carrier 21 for holding the substrate Sw in a state in which the lower surface of the substrate serving as a film-forming surface is left open. It is thus so arranged that by means of a driving apparatus (not illustrated), the carrier 21 and further the substrate Sw can be moved at a predetermined velocity in one direction inside the vacuum chamber 1. As the substrate transfer apparatus 2 there can be used as known one and, therefore, no further description thereof will be made. On a bottom surface of the vacuum chamber 1 there are arranged a plurality of the evaporation sources DS₁ of the first embodiment at a distance from each other in the moving direction of the substrate Sw.

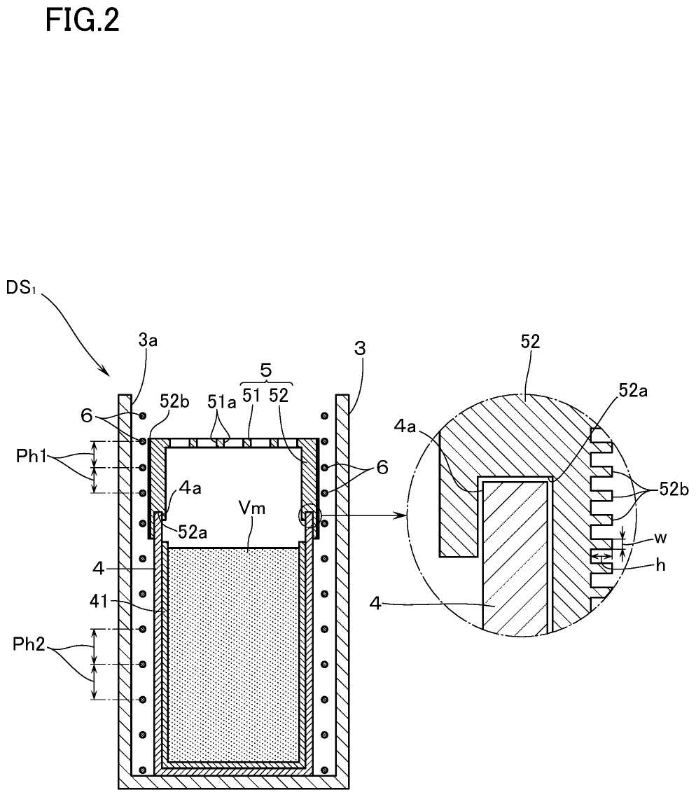

With reference also to FIG. 2, each of the evaporation sources DS₁ has the same construction and is provided with a storing container 3 of a bottomed cylindrical shape, the storing container being disposed on the bottom surface of the vacuum chamber 1 in a posture in which the opening 3a faces upward. A crucible 4 is stored inside the storing container 3 and, at the same time, an induction heating coil 6 is disposed between the storing container 3 and the crucible 4.

The crucible 4 has a bottomed cylindrical shape and is disposed on the lower surface of the storing container 3. The crucible 4 is detachably provided with a cap body 5 in such a manner as to close an opening on an upper surface (also called “an upper surface opening”) 4a of the crucible 4. The cap body 5 is provided with: a cover plate part 51 having opened therein a plurality of openings 51a (discharge parts 51a); and a peripheral wall part 52 which is vertically disposed from an outer edge of the cover plate part 51 downward. The lower end of the peripheral wall part 52 has formed therein a recessed part 52a which recesses upward. By fitting an upper end of the crucible 4 into the recessed part 52a, the cap body 5 is arranged to be detachably fitted into the crucible 4 (see the portion enclosed by a chained line in FIG. 2). In this case, although not illustrated in particular, projected parts are disposed on an upper end of the crucible 4 at a circumferential distance from one another so that each of the projected parts comes into point contact with the recessed part 52a of the cap body 5. The crucible 4 and the cap body 5 are made of electrically conductive material such as carbon, graphite, titanium, stainless steel (SUS), boron nitride (BN) and the like, or a material by processing a metallic film or a graphite film on the surface of ceramic material such as boron nitride and the like.

In addition, in FIG. 2, the portion enclosed by a dashed line is an enlargement of the peripheral wall part 52 of the cap body 5. On the outer surface of the peripheral wall part 52 of the cap body 5, there are vertically formed a plurality of projections 52b at an equal distance from one another, thereby repeating the recessions and projections. Each of the projections 52b is formed by machining in the form of countersinking the peripheral wall part 52 so as to have a profile of rectangle in cross section over an entire continuous length of the circumferencial surface. In this case, the number of the projections 52b, the height h from the outer surface of the peripheral wall part 52 of the projections 52b, and the width w in the vertical direction of the projections 52b are appropriately set depending on the temperature of heating the vapor deposition material Vm, the area of the peripheral wall part 52, the distance between the peripheral wall 52 and the induction heating coil 6 (so as to keep the induction heating coil 6 out of contact with the peripheral wall 52), or taking into consideration the ease of workability and the like. For example, the height h shall be set above 100 μm, and the width w shall be set within a range of 0.1 to 10 mm.

Inside the crucible 4 there is stored an inner crucible part 41. The inner crucible part 41 is made of a material with heat resistance and relatively small heat conductivity such as ceramics, titanium, and stainless steel. Inside the inner crucible part 41 the vapor deposition material Vm is filled. As the evaporation material Vm an organic material is appropriately selected depending on the thin film to be deposited on the substrate Sw, and the material in the form of granules or tablets is utilized. In this embodiment, a description is made of an example in which the inner crucible part 41 is filled with the vapor deposition material Vm, but without providing the inner crucible part 41 inside the crucible 4, the crucible 4 may be filled with the vapor deposition material Vm.

The induction heating coil 6 is wound at a predetermined winding pitch so as to cover the entire circumference of the crucible 4 and the cap body 5 is electrically connected to an AC power supply (not illustrated). In this arrangement, when the induction heating coil 6 is charged with AC current by the AC power supply inside the vacuum chamber 1 in a vacuum atmosphere, the crucible 4 and the cap body 5 get heated by the Jule heat that is generated by the resistance loss when the induction current (eddy current) flows through the crucible 4 and the cap body 5. In this embodiment, the winding pitch of the induction heating coil 6 is so arranged that the winding pitch Ph1 of the induction heating coil 6 positioned around the cap body 5 is smaller than the winding pitch Ph2 of the induction heating coil positioned around the crucible 4.

According to the above arrangement, in case a predetermined organic film is deposited on a lower surface of the substrate Sw by the above-mentioned vapor deposition apparatus Dm, once the induction heating coil 6 is charged with the AC power supply inside the vacuum chamber 1 in the vacuum atmosphere, the induction current (eddy current) flows through the crucible 4 and the cap body 5. At this time, as a result of having provided the outside surface of the cap body 5 with projections 52b each having a corner part, resistance loss will be augmented at the corner part (edge part) of each of the projections 52b. The calorific value improves when the magnetic flux density to work on the cap body 5 and the quality of material of the cap body 5 are supposed to be equal to a case, for comparison purpose, in which projections 52b are not provided. As a result, it is possible to cause the cap body 5 to generate heat on a priority basis so as to make the entire crucible inclusive of the cap body 5 into the top-heat state.

Further, according to this invention, by providing the outside surface of the peripheral wall part 52 of the cap body 5 with a plurality of circumferentially extending projections 52b, the distance in which the eddy current flows becomes longer, resulting in further augmentation in the resistance loss. It is thus possible to further augment the calorific value of the cap body 5 to surely attain the top-heat state of the entire crucible inclusive of the cap body 5. Furthermore, as a result of setting smaller the winding pitch Ph1 of the induction heating coil 6 that is positioned around the cap body 5 than the winding pitch ph2 of the induction heating coil 6 that is positioned around the crucible 4, the crucible 4 is restrained from getting heated. As a consequence, the entire crucible inclusive of the cap body 5 can surely be made into the top-heat state.

In order to confirm the above-mentioned effects, the following evaluation was made using the above-mentioned vapor deposition source DS₁. In other words, by using the crucible 4 and the cap body 5 which are made of titanium, there were provided, over the entire circumference, a plurality of projections 52b having a height h of 100 μm from the external surface of the peripheral wall part 52 and a vertical width w of 2.0 mm, and an evaluation was made of the resistance loss of the crucible 4 and the cap body 5. At this time, the winding pitch Ph1 of the induction heating coil 6 that was positioned around the cap body 5 was set at 10 mm, and the winding pitch Ph2 of the induction heating coil 6 that was positioned around the crucible 4 was set at 30 mm, and the coil 6 was charged with electricity of 20 A at a frequency of 200 kHz. As a comparative experiment, by using a sample having no projections on the peripheral wall of the cap body 5, the resistance losses of the crucible 4 and the cap body 5 were evaluated.

In the comparative experiment, the resistance loss of the crucible 4 was 8.4 W/m³, and the resistance loss of the cap body 5 was 4.2 W/m³. The resistance loss of the cap body 5 was smaller than the resistance loss of the crucible 4. On the other hand, in the experiment of this invention, the resistance loss of the crucible 4 was 3.2 W/m³, and the resistance loss of the cap body 5 was 8.6 W/m³. The resistance loss of the cap body 5 was thus larger than the resistance loss of the crucible 4. It has thus been confirmed that the top-heat state has been attained.

Descriptions have so far been made of the embodiments of this invention. As long as the technical concept of this invention is not deviated, various modifications can be made. In the above-mentioned evaporation source DS₁ according to the above-mentioned first embodiment, a description was made of an example in which projections 52b having disposed, on an outside surface of the peripheral wall part 52, a plurality of cross-sectional shape elongated vertically (longitudinal direction of the crucible 4). The position in which the projections 52b are disposed need not be limited to the above-mentioned example, but the projections may be disposed, e.g., on an outside surface of the lid plate part 51. In addition, the shape of the projections can augment the resistance loss at the time of flowing of the induction current (eddy current) and, at the same time, as long as the projections have a predetermined length, the shape of the projections need not be limited to the above. It may be so arranged that the shape of the projections 52b has a cross section of a rounded profile to such a degree as can increase the resistance loss.

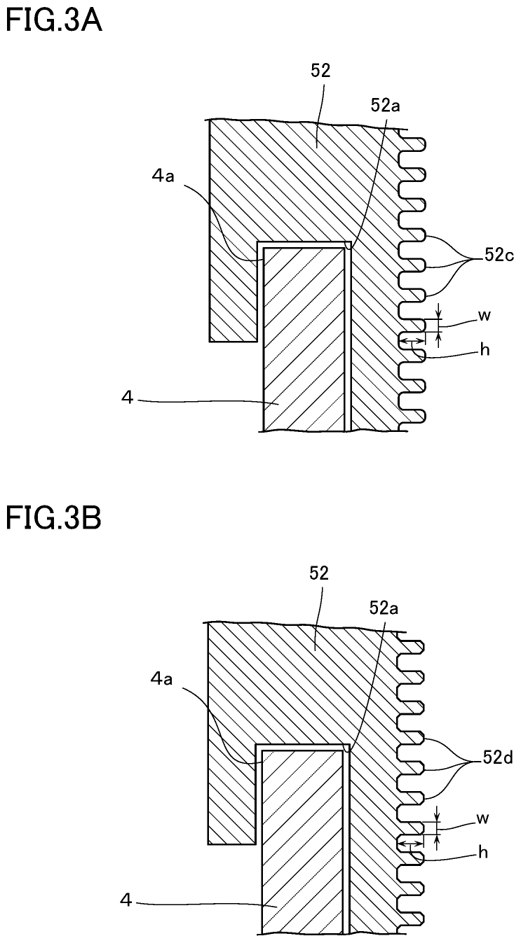

In other words, as shown in FIGS. 3(a) and 3(b), bearing the same reference numerals with reference to the same members or elements, the evaporation source relating to a modified example may be that the sectional shape of the projections may be oblong rounded to such a degree as to augment the resistance loss (projection 52c in FIG. 3(a)) or substantially pentagonal in section having chamfered surface (projection 52d in FIG. 3(b)). In these shapes of the corner parts, the outside surface of the peripheral wall part 52 became a shape to repeat the projection/recession. As a result, the resistance loss will be augmented by enlarging the distance in which the eddy current flows, thereby increasing the calorific value of the cap body 5.

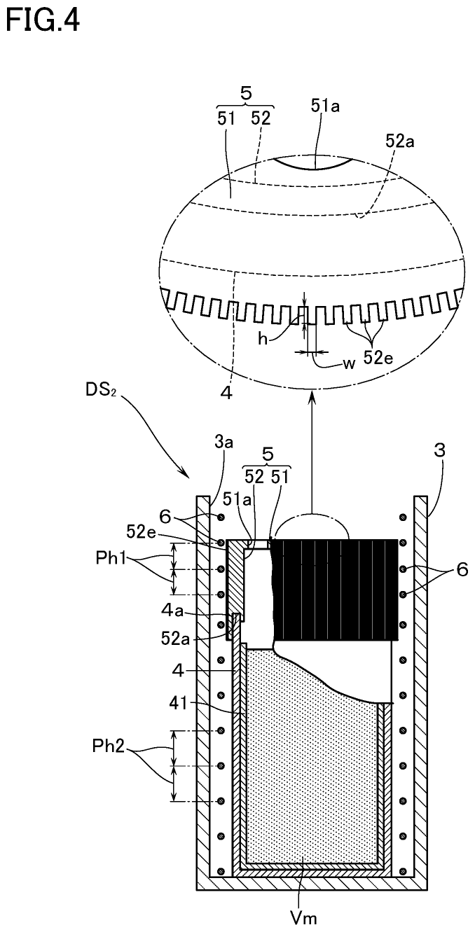

In the evaporation source DS₁ according to the above-mentioned first embodiment, a description was made of an example in which a plurality of projections 52b extend in the circumferential direction of the peripheral wall part 25, but the pattern of the projections is not limited thereto. With reference to FIG. 4 in which the same reference numerals have been assigned to the same members or elements, in the evaporation source DS₂ according to a second embodiment, a plurality of projections are provided in a pattern in which each of the projections 52e extends in the vertical direction of the peripheral wall part 52. It is to be noted that the portion enclosed by a chained line in FIG. 4 is an enlarged view showing the peripheral wall part 52 of the cap body 5 as seen from an upper side. Further, it is also considered to provide a lattice-shaped pattern in which each of the circumferentially extended projections 52b and each of the vertically extended projections 52e cross each other, or a spirally shaped pattern around a generating line of the peripheral part 52.

Furthermore, in the above-mentioned first embodiment, a description was made of an example in which the winding pitch Ph1, at a position around the cap body 5, of the induction heating coil 6 was set smaller than the winding pitch Ph2, at a position around the crucible 4, of the induction heating coil 6. Without being limited to the above, the winding pitch of the induction heating coil may be set equally in relation to the one positioned around the cap body 5 and the one positioned around the crucible 4.

### EXPLANATION OF MARKS

Dm vapor deposition apparatus
DS₁, DS₂ vapor deposition source
Sw substrate (to-be-deposited object)
Vm vapor deposition material
1 vacuum chamber
4 crucible
4a upper surface opening
5 cap body
51 lid plate part
51a discharge part
52 peripheral wall part
52b-52e projections
6 induction heating coil
Ph1 winding pitch of induction heating coil positioned around a cap body
Ph2 winding pitch of induction heating coil positioned around a crucible

1. An evaporation source disposed inside a vacuum chamber, the evaporation source being adapted for use in a vapor deposition apparatus which performs vapor deposition on a to-be-deposited object, the evaporation source comprising:
a crucible filled with vapor deposition material;
a cap body for closing an upper surface opening of the crucible;
an induction heating coil disposed around the crucible and the cap body; and
a discharge part disposed in the cap body in order to allow for passage therethrough of the vapor deposition material that has been evaporated or sublimated by heating,
wherein the cap body is provided on an outside surface thereof with projections each having a corner part.

2. The evaporation source adapted for use in a vapor deposition apparatus according to claim 1, wherein the cap body comprises: a cover plate part provided with the discharge part; and a peripheral wall part vertically disposed from an outer edge of the cover plate part downward such that: a lower end of the peripheral wall part is detachably fitted onto an upper end of the crucible and that; an outside surface of the peripheral wall part is provided with a plurality of the projections in a manner to be vertically or circumferentially extended.

3. The evaporation source adapted for use in a vapor deposition apparatus according to claim 1, wherein the winding pitch of the induction heating coil that is positioned around the cap body is set smaller than the winding pitch of the induction heating coil that is positioned around the crucible.
